(19) United States
(12) Patent Application Publication
(10) Pub. No.: US 2026/0015284 A1
(43) Pub. Date: Jan. 15, 2026

(54) APPARATUS FOR MANUFACTURING COVER WINDOW

(71) Applicant: Samsung Display Co., LTD., Yongin-si (KR)

(72) Inventors: Byoung Yul SHIM, Yongin-si (KR); Hyun Chul KIM, Yongin-si (KR); Kang Duk CHOI, Yongin-si (KR); Seung Pyo HONG, Yongin-si (KR)

(73) Assignee: Samsung Display Co., LTD., Yongin-si (KR)

(21) Appl. No.: 19/171,645

(22) Filed: Apr. 7, 2025

(30) Foreign Application Priority Data
Jul. 9, 2024 (KR) 10-2024-0090105

(51) Int. Cl. C03C 15/00; H05K 5/03

(52) U.S. Cl. CPC C03C 15/00; H05K 5/03

(57) ABSTRACT

An apparatus for manufacturing a cover window includes a first screen, a second screen spaced apart from the first screen, and a screen opening disposed between the first screen and the second screen, wherein each of the first screen and the second screen includes a pattern portion disposed adjacent to the screen opening, the pattern portion of each of the first screen and the second screen includes two or more holes spaced apart from each other, and widths of the two or more holes are different from each other.

### CROSS REFERENCE TO RELATED APPLICATION(S)

This application claims priority to and benefits of Korean Patent Application No. 10-2024-0090105 under 35 U.S.C. 119, filed on Jul. 9, 2024, in the Korean Intellectual Property Office (KIPO), the entire contents of which are incorporated herein by reference.

### BACKGROUND

### 1. Technical Field

The disclosure relates to an apparatus for manufacturing a cover window.

### 2. Description of the Related Art

As the information society develops, demands for display devices for displaying images are increasing in various forms. The display devices may be liquid crystal displays, field emission displays, or light emitting displays. The light emitting displays include an organic light emitting display including an organic light emitting diode element as a light emitting element and an inorganic light emitting display including an inorganic light emitting diode element as a light emitting element.

In order to increase portability of a display device while providing a wide display screen, a bendable display device whose display area can be bent or a foldable display device whose display area can be folded have been released recently.

A cover window included in these flexible display devices also has flexible characteristics. The cover window is required to have basic physical properties that satisfy folding characteristics, have no screen distortion, and have sufficient strength to withstand repeated touches of a touch pen, etc. and certain pressure.

### SUMMARY

Aspects of the disclosure provide an apparatus for manufacturing a cover window with improved flatness of a slim cover window.

Aspects of the disclosure also provide an apparatus for manufacturing a cover window with a reduced material for manufacturing a slim cover window.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, an apparatus for manufacturing a cover window may include a first screen, a second screen spaced apart from the first screen, and a screen opening disposed between the first screen and the second screen. Each of the first screen and the second screen may include a pattern portion disposed adjacent to the screen opening, the pattern portion of each of the first screen and the second screen may include two or more holes spaced apart from each other, and widths of the two or more holes may be different from each other.

In an embodiment, the widths of the two or more holes may increase as a distance to the screen opening decreases.

In an embodiment, the apparatus may further include a screen frame surrounding the first screen and the second screen in a plan view.

In an embodiment, the first screen and the second screen may be spaced apart from each other in a first direction, and the two or more holes may extend in a second direction intersecting the first direction.

In an embodiment, the first screen and the second screen may be spaced apart from each other in a first direction, and each of the two or more holes may include a plurality of holes spaced apart from each other in a second direction intersecting the first direction.

In an embodiment, ends of the two or more holes may be spaced apart from the screen frame.

In an embodiment, the apparatus may further include a frame fixing part fixing the screen frame. The screen frame may be spaced apart from a target window by the frame fixing part.

In an embodiment, a size of the screen opening may be larger than sizes of the two or more holes.

In an embodiment, the apparatus may further include a squeegee disposed on the first screen and the second screen.

In an embodiment, the apparatus may further include a stage disposed below the first screen and the second screen.

In an embodiment, the apparatus may further include an ink supply part ejecting ink containing an etchant and disposed above the first screen and the second screen.

In an embodiment, the apparatus may further include a first auxiliary screen disposed below the first screen, and a second auxiliary screen disposed below the second screen. Each of the first auxiliary screen and the second auxiliary screen may include a mesh pattern overlapping the pattern portion of the first screen or the second screen in a plan view. The mesh pattern may include a plurality of mesh holes having a constant shape and size in a plan view.

In an embodiment, the first auxiliary screen and the second auxiliary screen may be spaced apart from each other with the screen opening interposed between the first auxiliary screen and the second auxiliary screen.

In an embodiment, the first screen and the second screen may include a corrosion-resistant material.

According to an embodiment of the disclosure, an apparatus for manufacturing a cover window may include a stage, a screen part disposed on the stage and including a screen frame, a first screen and a second screen surrounded by the screen frame and spaced apart from each other in a plan view, and a screen opening disposed between the first screen and the second screen, and a squeegee disposed on the screen part. Each of the first screen and the second screen may include a pattern portion disposed adjacent to the screen opening, the pattern portion of each of the first screen and the second screen may include a first hole and a second hole spaced apart from each other, the first hole may be disposed closer to the screen opening than the second hole, and a size of the first hole may be larger than a size of the second hole.

In an embodiment, the apparatus may further include a frame fixing part disposed on the stage and fixing the screen part such that the screen part is spaced apart from the stage.

In an embodiment, a size of the screen opening may be larger than the sizes of the first hole and the second hole.

In an embodiment, the screen part may include a corrosion-resistant material.

In an embodiment, the apparatus may further include an ink supply part ejecting ink containing an etchant and disposed above the screen unit.

According to an embodiment of the disclosure, an electronic device may include a processor to provide input image data, and a display device to display an image based on the input image data. The display device may include a display panel and a cover window, and the cover window may be manufactured using the apparatus.

According to an apparatus for manufacturing a cover window according to an embodiment of the disclosure, the flatness of a slim cover window may be improved.

According to an apparatus for manufacturing a cover window according to an embodiment of the disclosure, a material for manufacturing a slimming cover window may be reduced.

However, the effects of the disclosure are not restricted to the one set forth herein. The above and other effects of the disclosure will become more apparent to one of daily skill in the art to which the disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating an unfolded state of a display device according to an embodiment;

FIG. 2 is a perspective view illustrating a folded state of the display device according to the embodiment;

FIG. 3 is a perspective view illustrating an unfolded state of a display device according to an embodiment;

FIG. 4 is a perspective view illustrating a folded state of the display device according to the embodiment of FIG. 3;

FIG. 5 is a schematic cross-sectional view of a display device according to an embodiment;

FIG. 6 is a schematic cross-sectional view of a display panel according to an embodiment;

FIG. 7 is a schematic cross-sectional view of a window composite layer according to an embodiment;

FIG. 8 is a cross-sectional photograph of a portion of a cover window according to a comparative example;

FIG. 9 is a perspective view of an apparatus for manufacturing a cover window according to an embodiment;

FIGS. 10 and 11 are schematic cross-sectional views taken along line X1-X1′ of FIG. 9;

FIG. 12 is a schematic cross-sectional view taken along line X2-X2′ of FIG. 9;

FIG. 13 is an enlarged view of area A of FIG. 12;

FIG. 14 is a plan view of a screen part according to an embodiment;

FIG. 15 is a plan view of a screen part according to an embodiment;

FIG. 16 is a plan view of a screen part according to an embodiment;

FIG. 17 is a schematic cross-sectional view of an apparatus for manufacturing a cover window according to an embodiment;

FIG. 18 is an enlarged view of area B of FIG. 17;

FIG. 19 is a plan view of a screen part of a cover window according to an embodiment;

FIG. 20 is a flowchart illustrating a method of manufacturing a cover window according to an embodiment;

FIGS. 21 and 22 are schematic cross-sectional views illustrating operation S100 of FIG. 20;

FIG. 23 is a schematic cross-sectional view illustrating operation S200 of FIG. 20;

FIG. 24 is a schematic cross-sectional view illustrating operation S300 of FIG. 20; and

FIGS. 25 and 26 are enlarged views of area C of FIG. 24.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

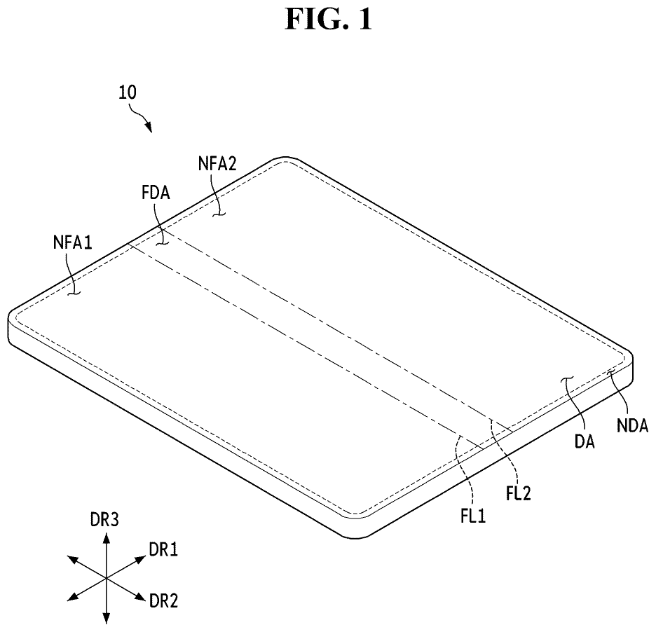

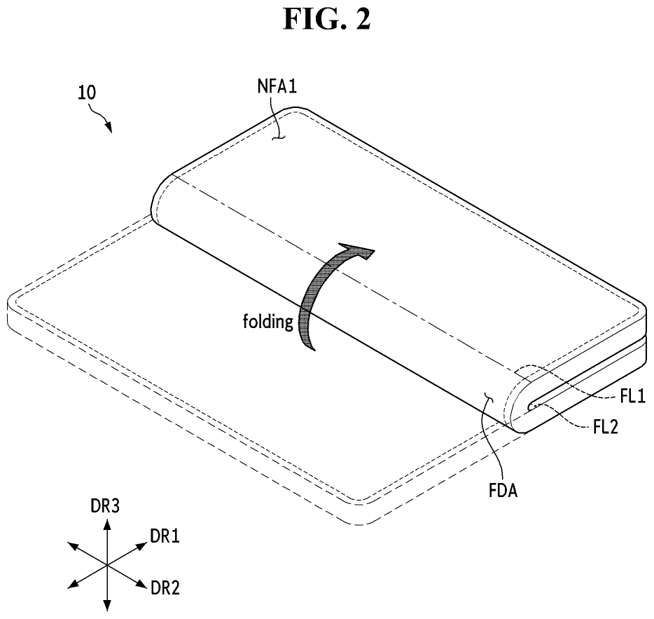

FIG. 1 is a perspective view illustrating an unfolded state of a display device 10 according to an embodiment. FIG. 2 is a perspective view illustrating a folded state of the display device 10 according to the embodiment.

Referring to FIGS. 1 and 2, FIG. 1 schematically illustrates a first state in which the display device 10 is not folded at folding lines FL1 and FL2, and FIG. 2 schematically illustrates a second state in which the display device 10 is folded at the folding lines FL1 and FL2.

The display device 10 according to an embodiment may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (IoT) devices.

In the drawings, a first direction DR1 may be a direction parallel to a side of the display device 10 in a plan view, for example, may be a horizontal direction of the display device 10. A second direction DR2 may be a direction parallel to another side in contact with the above side of the display device 10 in a plan view, for example, may be a vertical direction of the display device 10. A third direction DR3 may be a thickness direction of the display device 10.

The display device 10 may have a quadrangular shape such as a rectangle in a plan view. Each corner of the display device 10 may be right-angled or rounded in a plan view. A front surface of the display device 10 may include two short sides in the first direction DR1 and two long sides in the second direction DR2.

The display device 10 may include a display area DA and a non-display area NDA. The shape of the display area DA may follow the shape of the display device 10 in a plan view. For example, in case that the display device 10 is rectangular in a plan view, the display area DA may also be rectangular in a plan view.

The display area DA may be an area which includes multiple pixels to display an image. The non-display area NDA may be an area which does not include pixels and thus does not display an image. The non-display area NDA may be disposed adjacent to the display area DA. The non-display area NDA may surround the display area DA, but the disclosure is not limited thereto. In another embodiment, the display area DA may be partially surrounded by the non-display area NDA.

The display device 10 may maintain the first state which is the unfolded state and the second state which is the folded state. In an embodiment, the display device 10 may be folded in an in-folding manner so that portions of the display area DA face each other as illustrated in FIG. 2, and portions of the front surface of the display device 10 may face each other in case that the display device 10 is folded. In an embodiment, the display device 10 may be folded in an out-folding manner so that portions of a back surface of the display device 10 face each other.

The display device 10 may include a folding area FDA, a first non-folding area NFA1, and a second non-folding area NFA2. The folding area FDA may be an area in which the display device 10 is bendable or foldable. The first non-folding area NFA1 and the second non-folding area NFA2 may be areas in which the display device 10 is not bendable or foldable. In an embodiment, the first non-folding area NFA1 and the second non-folding area NFA2 may be flat areas of the display device 10.

The first non-folding area NFA1 may be disposed on a side, e.g., a left side of the folding area FDA. The second non-folding area NFA2 may be disposed on another side, e.g., a right side of the folding area FDA. The folding area FDA may be an area which is defined by a first folding line FL1 and a second folding line FL2 and an area in which the display device 10 is bendable with a curvature. The first folding line FL1 may be a boundary between the folding area FDA and the first non-folding area NFA1, and the second folding line FL2 may be a boundary between the folding area FDA and the second non-folding area NFA2.

The first folding line FL1 and the second folding line FL2 may extend in the second direction DR2 as illustrated in FIGS. 1 and 2, and the display device 10 may be foldable based on the second direction DR2. Therefore, since a length of the display device 10 in the first direction DR1 may be reduced by about half, a user may readily carry the display device 10.

The first non-folding area NFA1 may be disposed on a side, e.g., the left side of the folding area FDA. The second non-folding area NFA2 may be disposed on another side, e.g., the right side of the folding area FDA. The left side may be a side in the first direction DR1, and the right side may be another side in the first direction DR1.

In case that the first folding line FL1 and the second folding line FL2 extend in the second direction DR2 as illustrated in FIGS. 1 and 2, a length of the folding area FDA in the second direction DR2 may be greater than a length of the folding area FDA in the first direction DR1, a length of the first non-folding area NFA1 in the second direction DR2 may be greater than a length of the first non-folding area NFA1 in the first direction DR1, and a length of the second non-folding area NFA2 in the second direction DR2 may be greater than a length of the second non-folding area NFA2 in the first direction DR1.

Each of the display area DA and the non-display area NDA may overlap at least one of the folding area FDA, the first non-folding area NFA1, and the second non-folding area NFA2 in a thickness direction of the display device 10. As shown in FIGS. 1 and 2, each of the display area DA and the non-display area NDA may overlap the folding area FDA, the first non-folding area NFA1, and the second non-folding area NFA2 in the thickness direction of the display device 10.

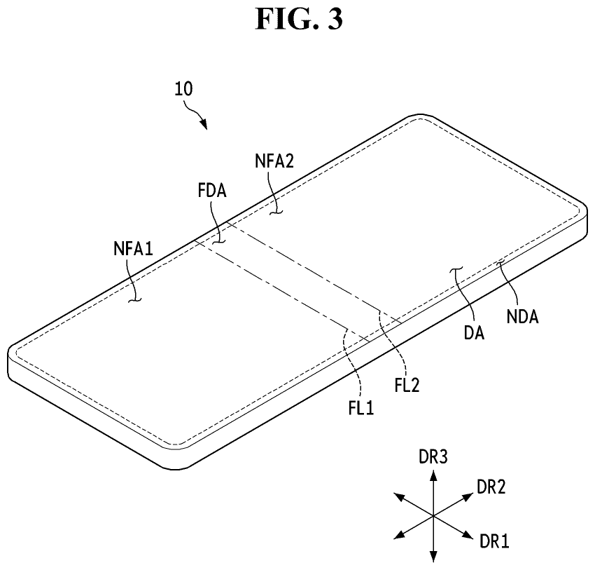

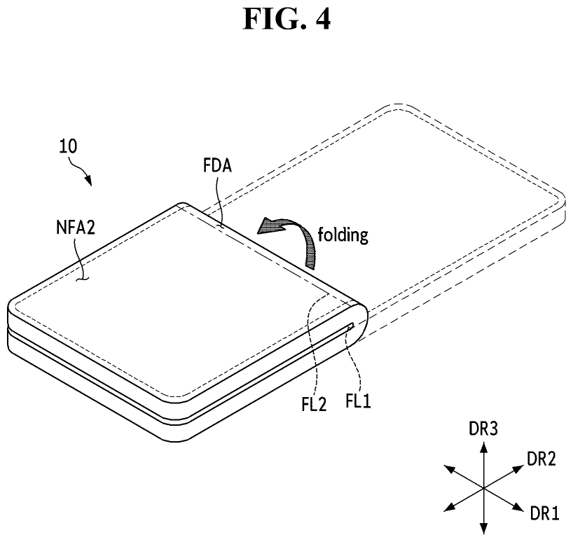

FIG. 3 is a perspective view illustrating an unfolded state of a display device 10 according to an embodiment. FIG. 4 is a perspective view illustrating a folded state of the display device 10 according to the embodiment.

Referring to FIGS. 3 and 4 in addition to FIGS. 1 and 2, FIG. 3 schematically illustrates a first state in which the display device 10 is not folded at folding lines FL1 and FL2, and FIG. 4 schematically illustrates a second state in which the display device 10 is folded at the folding lines FL1 and FL2.

The embodiment of FIGS. 3 and 4 is different from the embodiment of FIGS. 1 and 2 only in that a first folding line FL1 and a second folding line FL2 extend in the first direction DR1, and the display device 10 is foldable in the second direction DR2 so that a length of the display device 10 in the second direction DR2 may be reduced by about half. Therefore, in FIGS. 3 and 4, a description of elements and features identical to those of the embodiment of FIGS. 1 and 2 will be omitted.

In the first state in which the display device 10 is unfolded, long sides of the display device 10 may extend along the second direction DR2, and short sides of the display device 10 may extend along the first direction DR1.

The first folding line FL1 and the second folding line FL2 may extend in the first direction DR1 as illustrated in FIGS. 3 and 4, and the display device 10 may be foldable based on the first direction DR1.

A first non-folding area NFA1 may be disposed on a side, e.g., a lower side of a folding area FDA. A second non-folding area NFA2 may be disposed on another side, e.g., an upper side of the folding area FDA. Here, the upper side may be a side in the second direction DR2, and the lower side may be another side in the second direction DR2.

In case that the first folding line FL1 and the second folding line FL2 extend in the first direction DR1 as illustrated in FIGS. 3 and 4, a length of the folding area FDA in the first direction DR1 may be greater than a length of the folding area FDA in the second direction DR2, a length of the first non-folding area NFA1 in the second direction DR2 may be greater than a length of the first non-folding area NFA1 in the first direction DR1, and a length of the second non-folding area NFA2 in the second direction DR2 may be greater than a length of the second non-folding area NFA2 in the first direction DR1.

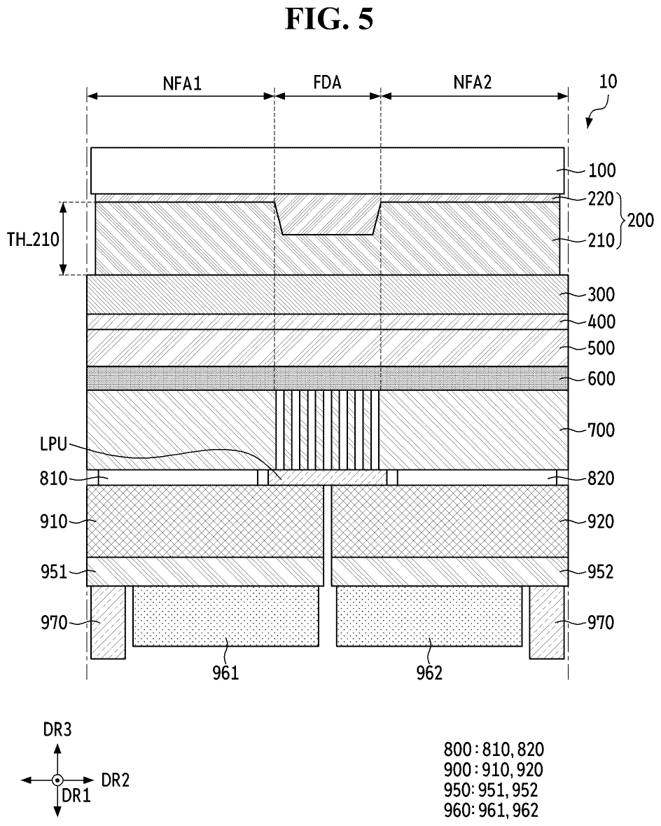

FIG. 5 is a schematic cross-sectional view of a display device 10 according to an embodiment.

Referring to FIG. 5, the display device 10 according to an embodiment may include an upper protective member 100, a window composite layer 200, an optical member 300, a display panel 400, a panel protection member 500, a barrier film 600, a panel support member 700, an adhesive member 800, a lower anti-view member LPU, a digitizer member 900, a metal support member 950, a buffer member 960, and a penetration prevention member 970.

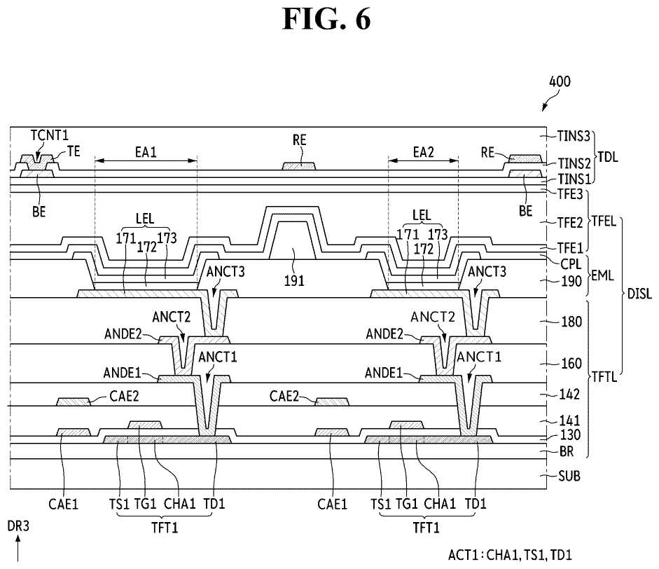

The display panel 400 may be a panel that displays an image. The display panel 400 may be an organic light emitting display panel including an organic light emitting layer, a quantum dot light emitting display panel including a quantum dot light emitting layer, an inorganic light emitting display panel using an inorganic semiconductor element as a light emitting element, or a micro-light emitting display panel using a micro-light emitting diode as a light emitting element. An embodiment that the display panel 400 is an organic light emitting display panel will be described below, but the disclosure is not limited thereto. The detailed structure of the display panel 400 will be described below with reference to FIG. 6.

The optical member 300 may be disposed on a surface of the display panel 400. For example, the optical member 300 may be disposed on an upper surface of the display panel 400. The optical member 300 may include a polarizing film and/or a phase difference film. The optical member 300 may reduce reflection of external light.

The window composite layer 200 may be disposed on the optical member 300. The window composite layer 200 may include a cover window 210 and a resin 220.

The cover window 210 may protect the display panel 400 from external impact. The cover window 210 may enhance the impact resistance of the display device 10. The cover window 210 may be made of a transparent material. For example, the cover window 210 may include glass or a plastic. In an embodiment, the cover window 210 may be ultra-thin glass (UTG) having a thickness less than or equal to about 0.3 mm. In another embodiment, the cover window 210 may include a transparent polyimide film. In an embodiment, a thickness TH_210 of the cover window 210 may be, but is not limited to, in a range of about 30 μm to about 300 μm. For example, the thickness TH_210 of the cover window 210 may be, but is not limited to, in a range of about 60 μm to about 250 μm.

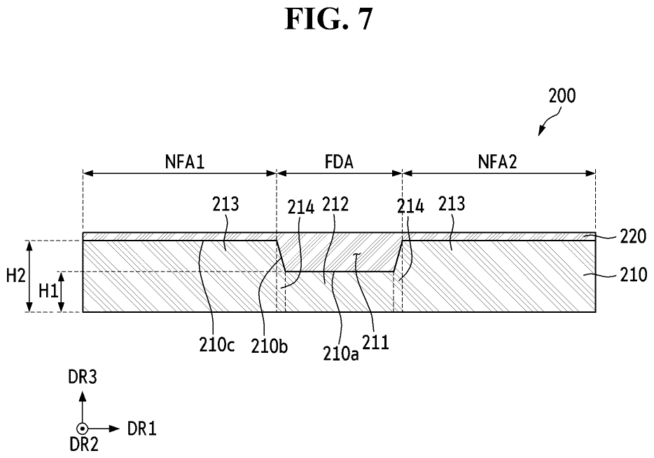

In an embodiment, the cover window 210 of the display device 10 may include a groove 211 (see FIG. 7) disposed in a folding area FDA. Accordingly, the stress applied to the folding area FDA in case that the display device 10 is folded may be minimized. The structure of the cover window 210 and the groove 211 will be described below with reference to FIG. 7.

The resin 220 may be disposed on the cover window 210. For example, the resin 220 may be disposed between the cover window 210 and the upper protective member 100. The resin 220 may flatten a step formed by the groove 211 (see FIG. 7) of the cover window 210. The resin 220 may include at least one of an ultraviolet curable resin, a thermo-curable resin, and a natural curable resin. In some embodiments, the resin 220 may cover an upper surface of the cover window 210. Accordingly, the resin 220 may prevent shattering of the cover window 210.

The upper protective member 100 may be disposed on the window composite layer 200. The upper protective member 100 may perform at least one of shatter prevention, shock absorption, scratch prevention, fingerprint prevention, and glare prevention of the window composite layer 200. The upper protective member 100 may include at least one of polyacrylate, polyethylene terephthalate (PET), and polyimide (PI).

The panel protection member 500 may be disposed on another surface of the display panel 400. For example, the panel protection member 500 may be disposed on a lower surface of the display panel 400. The panel protection member 500 may support the display panel 400 and protect the lower surface of the display panel 400. The panel protection member 500 may include a plastic such as polyethylene terephthalate (PET) or polyimide. Although the panel protection member 500 is also disposed in the folding area FDA of the display device 10 in the drawing, the disclosure is not limited thereto. For example, the panel protection member 500 in the folding area FDA of the display device 10 may be removed so that the display device 10 may be more readily foldable.

The barrier film 600 may be disposed on the panel protection member 500. For example, the barrier film 600 may be disposed on a lower surface of the panel protection member 500. The barrier film 600 may be a member for reinforcing the impact resistance of the display device 10.

The panel support member 700 may be disposed on the barrier film 600. For example, the panel support member 700 may be disposed on a lower surface of the barrier film 600. The panel support member 700 may be a rigid member whose shape or volume is not readily changed by external pressure. Since the panel support member 700 is disposed on the lower surface of the display panel 400 and is a rigid member whose shape or volume is not readily changed by external pressure, the panel support member 700 may support the display panel 400.

In an embodiment, the panel support member 700 may include a polymer including carbon fibers or glass fibers. Since the panel support member 700 is formed of a polymer including carbon fibers or glass fibers, the panel support member 700 may allow a magnetic field or electromagnetic signal of the digitizer member 900 to pass therethrough. Therefore, the panel support member 700 that can support the display panel 400 while not lowering the touch sensitivity of the digitizer member 900 may be provided.

In an embodiment, the panel support member 700 may be a metal plate. For example, the panel support member 700 may be a metal plate made of a metal or a metal alloy. The panel support member 700 may include, but is not limited to, copper (Cu), aluminum (Al), stainless steel, and/or an alloy thereof.

The panel support member 700 may include a grid pattern in the folding area FDA that is readily bendable in the folding area FDA. Since the panel support member 700 includes the grid pattern in the folding area FDA, the panel support member 700 may be readily bendable in case that the display device 10 is folded.

The lower anti-view member LPU may be disposed on the panel support member 700. For example, the lower anti-view member LPU may be disposed on a lower surface of the panel support member 700. The lower anti-view member LPU may overlap the folding area FDA in the thickness direction of the display device 10. The lower anti-view member LPU and the adhesive member 800 may be disposed on a same layer. The lower anti-view member LPU may be disposed between a first adhesive member 810 and a second adhesive member 820. The lower anti-view member LPU may prevent the grid pattern of the panel support member 700 from being visible from the outside. In an embodiment, the lower anti-view member LPU may include a flexible material to reduce the folding stress of the display device 10. For example, the lower anti-view member LPU may include thermoplastic polyurethane (TPU).

The adhesive member 800 may be disposed on the panel support member 700. For example, the adhesive member 800 may be disposed on the lower surface of the panel support member 700. The adhesive member 800 may be disposed between the panel support member 700 and the digitizer member 900. The panel support member 700 and the digitizer member 900 may be coupled to each other by the adhesive member 800. The adhesive member 800 may include a transparent adhesive such as a pressure sensitive adhesive (PSA) or an optically clear adhesive (OCA). The adhesive member 800 may include an acrylic adhesive material.

In some embodiments, the adhesive member 800 may include a first adhesive member 810 overlapping a first digitizer member 910 and a second adhesive member 820 overlapping a second digitizer member 920 in the thickness direction of the display device 10. The first adhesive member 810 and the second adhesive member 820 may be spaced apart from each other with the lower anti-view member LPU interposed between the first adhesive member 810 and the second adhesive member 820.

The digitizer member 900 may be disposed on the panel support member 700. For example, the digitizer member 900 may be disposed on the lower surface of the panel support member 700. The digitizer member 900 may include a first digitizer member 910 and a second digitizer member 920. The first digitizer member 910 and the second digitizer member 920 may be attached to the lower surface of the panel support member 700 by the first adhesive member 810 and the second adhesive member 820, respectively.

The first digitizer member 910 and the second digitizer member 920 may not be disposed in the folding area FDA to reduce the folding stress of the display device 10. The first digitizer member 910 may be disposed in a first non-folding area NFA1, and the second digitizer member 920 may be disposed in a second non-folding area NFA2. A gap between the first digitizer member 910 and the second digitizer member 920 may overlap the folding area FDA in the thickness direction of the display device 10, and may be smaller than a width of the folding area FDA. The width of the folding area FDA may be a length of the folding area FDA in the second direction DR2.

The first digitizer member 910 and the second digitizer member 920 may include electrode patterns for sensing the approach or touch of an electronic pen such as a stylus pen that supports electromagnetic resonance (EMR). The first digitizer member 910 and the second digitizer member 920 may sense a magnetic field or electromagnetic signal emitted from the electronic pen based on the electrode patterns and determine a point, at which the sensed magnetic field or electromagnetic signal is greatest, as touch coordinates.

Magnetic metal powder may be disposed on a lower surface of the first digitizer member 910 and a lower surface of the second digitizer member 920, and a magnetic field or electromagnetic signal passing through the first digitizer member 910 and the second digitizer member 920 may flow into the magnetic metal powder. Therefore, the magnetic metal powder may reduce the emission of the magnetic field or electromagnetic signal of the first digitizer member 910 and the second digitizer member 920 to a lower surface of the display device 10.

In some embodiments, the digitizer member 900 may be omitted.

The metal support member 950 may include a first metal support member 951 and a second metal support member 952. The first metal support member 951 may be disposed on the lower surface of the first digitizer member 910, and the second metal support member 952 may be disposed on the lower surface of the second digitizer member 920.

The first metal support member 951 and the second metal support member 952 may not be disposed in the folding area FDA to reduce the folding stress of the display device 10. The first metal support member 951 may be disposed in the first non-folding area NFA1, and the second metal support member 952 may be disposed in the second non-folding area NFA2. A gap between the first metal support member 951 and the second metal support member 952 may overlap the folding area FDA in the thickness direction of the display device 10, and may be smaller than the width of the folding area FDA.

The first metal support member 951 and the second metal support member 952 may include a material having high rigidity to support the first digitizer member 910 and the second digitizer member 920. For example, the first metal support member 951 and the second metal support member 952 may include stainless steel such as S31600 (SUS316).

The buffer member 960 may include a first buffer member 961 and a second buffer member 962. The first buffer member 961 and the second buffer member 962 may prevent the panel support member 700 and the digitizer member 900 from being damaged by absorbing external shock. The first buffer member 961 and the second buffer member 962 may include an elastic material such as a sponge formed by foaming rubber, a urethane-based material, or an acrylic-based material.

The first buffer member 961 may be disposed on a lower surface of the first metal support member 951, and the second buffer member 962 may be disposed on a lower surface of the second metal support member 952. The first buffer member 961 and the second buffer member 962 may not be disposed in the folding area FDA to reduce the folding stress of the display device 10. The first buffer member 961 may be disposed in the first non-folding area NFA1, and the second buffer member 962 may be disposed in the second non-folding area NFA2. A gap between the first buffer member 961 and the second buffer member 962 may overlap the folding area FDA in the thickness direction of the display device 10, and may be smaller than the width of the folding area FDA.

The penetration prevention member 970 may be disposed on the lower surface of the first metal support member 951 and the lower surface of the second metal support member 952. The penetration prevention member 970 may be disposed adjacent to an edge of the first metal support member 951 and an edge of the second metal support member 952. Although the penetration prevention member 970 is disposed on both sides of the first buffer member 961 and the second buffer member 962 in the drawing, the disclosure is not limited thereto. For example, the penetration prevention member 970 may surround the first buffer member 961 and the second buffer member 962 in a plan view.

The penetration prevention member 970 may be a waterproof tape or a waterproof member attached to a front surface of a frame disposed on the lower surface of the first metal support member 951 and a lower surface of the buffer member 960. Accordingly, moisture or dust may be prevented from penetrating into the display device 10 by the penetration prevention member 970. For example, the display device 10 that is waterproof and dustproof may be provided.

In an embodiment, the penetration prevention member 970 may overlap, in the third direction DR3, a magnet for keeping the display device 10 folded without surrounding the first buffer member 961 and the second buffer member 962, and the penetration prevention member 970 may serve as a magnetism shielding member that may shield magnetic force to prevent the digitizer member 900 or the display panel 400 from being affected by the magnetic force of the magnet.

FIG. 6 is a schematic cross-sectional view of a display panel 400 according to an embodiment.

Referring to FIG. 6, the display panel 400 may include a substrate SUB, a display layer DISL disposed on the substrate SUB, and a touch sensing layer TDL disposed on the display layer DISL. The display layer DISL may include a thin-film transistor layer TFTL, a light emitting element layer EML, and an encapsulation layer TFEL.

The thin-film transistor layer TFTL may be disposed on the substrate SUB. The thin-film transistor layer TFTL may include a barrier layer BR, thin-film transistors TFT1, first capacitor electrodes CAE1, second capacitor electrodes CAE2, first anode connection electrodes ANDE1, second anode connection electrodes ANDE2, a gate insulating layer 130, a first interlayer insulating layer 141, a second interlayer insulating layer 142, a first planarization layer 160, and a second planarization layer 180.

The substrate SUB may be made of an insulating material such as a polymer resin. For example, the substrate SUB may be made of polyimide. The substrate SUB may be a flexible substrate that can be bent, folded, rolled, and the like.

The barrier layer BR may be disposed on the substrate SUB. The barrier layer BR may be a layer for protecting thin-film transistors of the thin-film transistor layer TFTL and light emitting layers 172 of the light emitting element layer EML from moisture introduced through the substrate SUB which may be vulnerable to moisture penetration. The barrier layer BR may be composed of multiple inorganic layers alternately stacked each other. For example, the barrier layer BR may have a multilayer in which one or more inorganic layers selected from a silicon nitride layer, a silicon oxynitride layer, a silicon oxide layer, a titanium oxide layer, and an aluminum oxide layer are alternately stacked each other.

The thin-film transistors TFT1 may be disposed on the barrier layer BR. An active layer ACT1 of each of the thin-film transistors TFT1 may be disposed on the barrier layer BR. The active layer ACT1 of each of the thin-film transistors TFT1 may include polycrystalline silicon, monocrystalline silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapping a gate electrode TG1 in the third direction DR3 which is the thickness direction of the substrate SUB. The source region TS1 may be disposed on a side of the channel region CHA1, and the drain region TD1 may be disposed on another side of the channel region CHA1. The source region TS1 and the drain region TD1 may be regions not overlapping the gate electrode TG1 in the third direction DR3. The source region TS1 and the drain region TD1 may be regions formed to have conductivity by doping a silicon semiconductor or an oxide semiconductor with ions or impurities.

The gate insulating layer 130 may be disposed on the active layers ACT1 of the thin-film transistors TFT1. The gate insulating layer 130 may be made of an inorganic layer, for example, a silicon nitride layer, a silicon oxynitride layer, a silicon oxide layer, a titanium oxide layer, or an aluminum oxide layer.

The gate electrodes TG1 of the thin-film transistors TFT1 and the first capacitor electrodes CAE1 may be disposed on the gate insulating layer 130. The gate electrodes TG1 may overlap the channel regions CHA1 in the third direction DR3. Although the gate electrodes TG1 and the first capacitor electrodes CAE1 are spaced apart from each other in FIG. 6, the disclosure is not limited thereto, and in another embodiment, the gate electrodes TG1 and the first capacitor electrodes CAE1 may be connected and integral with each other. Each of the gate electrodes TG1 and the first capacitor electrodes CAE1 may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The first interlayer insulating layer 141 may be disposed on the gate electrodes TG1 of the thin-film transistors TFT1 and the first capacitor electrodes CAE1. The first interlayer insulating layer 141 may be made of an inorganic layer, for example, a silicon nitride layer, a silicon oxynitride layer, a silicon oxide layer, a titanium oxide layer, or an aluminum oxide layer. The first interlayer insulating layer 141 may be composed of multiple inorganic layers.

The second capacitor electrodes CAE2 may be disposed on the first interlayer insulating layer 141. The second capacitor electrodes CAE2 may overlap the first capacitor electrodes CAE1 in the third direction DR3. In case that the gate electrodes TG1 and the first capacitor electrodes CAE1 are integral with each other, the second capacitor electrodes CAE2 may overlap the gate electrodes TG1 in the third direction DR3. Since the first interlayer insulating layer 141 has a dielectric constant, capacitors may be formed by the first capacitor electrodes CAE1, the second capacitor electrodes CAE2, and the first interlayer insulating layer 141 disposed between the first capacitor electrodes CAE1 and the second capacitor electrodes CAE2. Each of the second capacitor electrodes CAE2 may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The second interlayer insulating layer 142 may be disposed on the second capacitor electrodes CAE2. The second interlayer insulating layer 142 may be made of an inorganic layer, for example, a silicon nitride layer, a silicon oxynitride layer, a silicon oxide layer, a titanium oxide layer, or an aluminum oxide layer. The second interlayer insulating layer 142 may be composed of multiple inorganic layers.

The first anode connection electrodes ANDE1 may be disposed on the second interlayer insulating layer 142. Each of the first anode connection electrodes ANDE1 may be connected to the drain region TD1 of a thin-film transistor TFT1 through a first connection contact hole ANCT1 penetrating the gate insulating layer 130, the first interlayer insulating layer 141, and the second interlayer insulating layer 142. Each of the first anode connection electrodes ANDE1 may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The first planarization layer 160 may be disposed on the first anode connection electrodes ANDE1 to flatten steps due to the thin-film transistors TFT1. The first planarization layer 160 may be made of an organic material such as an acryl resin, an epoxy resin, a phenolic resin, a polyamide resin, or a polyimide resin.

The second anode connection electrodes ANDE2 may be disposed on the first planarization layer 160. Each of the second anode connection electrodes ANDE2 may be connected to a first anode connection electrode ANDE1 through a second connection contact hole ANCT2 penetrating the first planarization layer 160. Each of the second anode connection electrodes ANDE2 may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The second planarization layer 180 may be disposed on the second anode connection electrodes ANDE2. The second planarization layer 180 may be made of an organic material such as an acryl resin, an epoxy resin, a phenolic resin, a polyamide resin, or a polyimide resin.

The light emitting element layer EML including light emitting elements LEL and a bank 190 may be disposed on the second planarization layer 180. Each of the light emitting elements LEL may include a pixel electrode 171, a light emitting layer 172, and a common electrode 173.

The pixel electrode 171 may be disposed on the second planarization layer 180. The pixel electrode 171 may be connected to one of the second anode connection electrodes ANDE2 through a third connection contact hole ANCT3 penetrating the second planarization layer 180.

In a top emission structure in which light is emitted from the light emitting layer 172 toward the common electrode 173, the pixel electrode 171 may be made of a metal material having high reflectivity, such as a stacked structure (Ti/Al/Ti) of aluminum and titanium, a stacked structure (ITO/Al/ITO) of aluminum and indium tin oxide, a stacked structure (ITO/Ag/ITO) of silver and indium tin oxide, an APC alloy, or a stacked structure (ITO/APC/ITO) of an APC alloy and indium tin oxide. The APC alloy may be an alloy of silver (Ag), palladium (Pd), and copper (Cu).

The bank 190 may be formed on the second planarization layer 180 to separate the pixel electrodes 171 and define emission portions EA1 and EA2. The bank 190 may cover edges of the pixel electrodes 171. The bank 190 may be made of an organic material such as an acryl resin, an epoxy resin, a phenolic resin, a polyamide resin, or a polyimide resin.

Each of a first emission portion EA1 and a second emission portion EA2 may be an area in which the pixel electrode 171, the light emitting layer 172, and the common electrode 173 are sequentially stacked so that holes from the pixel electrode 171 and electrons from the common electrode 173 recombine together in the light emitting layer 172 to emit light.

The light emitting layer 172 may be disposed on the pixel electrode 171 and the bank 190. The light emitting layer 172 may include an organic material to emit light of a color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed commonly in the first emission portion EA1 and the second emission portion EA2.

In the top emission structure, the common electrode 173 may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In case that the common electrode 173 is made of a semi-transmissive conductive material, light output efficiency may be increased by a microcavity.

A spacer 191 may be disposed on the bank 190. The spacer 191 may support a mask during a process of manufacturing the light emitting layers 172. The spacer 191 may be made of an organic material such as an acryl resin, an epoxy resin, a phenolic resin, a polyamide resin, or a polyimide resin.

In some embodiments, the display panel 400 may further include a capping layer CPL disposed on the common electrodes 173. The capping layer CPL may include an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The encapsulation layer TFEL may be disposed on the common electrodes 173. The encapsulation layer TFEL may include at least one inorganic layer to prevent oxygen or moisture from permeating into the light emitting element layer EML. In an embodiment, the encapsulation layer TFEL may include at least one organic layer to protect the light emitting element layer EML from foreign substances such as dust. For example, the encapsulation layer TFEL may include a first encapsulating inorganic layer TFE1, an encapsulating organic layer TFE2, and a second encapsulating inorganic layer TFE3.

The first encapsulating inorganic layer TFE1 may be disposed on the common electrodes 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may have a multilayer in which one or more inorganic layers selected from a silicon nitride layer, a silicon oxynitride layer, a silicon oxide layer, a titanium oxide layer, and an aluminum oxide layer are alternately stacked each other. The encapsulating organic layer TFE2 may include an organic material such as an acryl resin, an epoxy resin, a phenolic resin, a polyamide resin, or a polyimide resin.

The touch sensing layer TDL may be disposed on the encapsulation layer TFEL. The touch sensing layer TDL may include a first touch insulating layer TINS1, connection electrodes BE, a second touch insulating layer TINS2, driving electrodes TE, sensing electrodes RE, and a third touch insulating layer TINS3.

The first touch insulating layer TINS1 may be disposed on the encapsulation layer TFEL. The first touch insulating layer TINS1 may be made of an inorganic layer, for example, a silicon nitride layer, a silicon oxynitride layer, a silicon oxide layer, a titanium oxide layer, or an aluminum oxide layer.

The connection electrodes BE may be disposed on the first touch insulating layer TINS1. Each of the connection electrodes BE may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The second touch insulating layer TINS2 may be disposed on the connection electrodes BE. The second touch insulating layer TINS2 may be made of an inorganic layer, for example, a silicon nitride layer, a silicon oxynitride layer, a silicon oxide layer, a titanium oxide layer, or an aluminum oxide layer. In another embodiment, the second touch insulating layer TINS2 may be made of an organic material such as an acryl resin, an epoxy resin, a phenolic resin, a polyamide resin, or a polyimide resin.

The driving electrodes TE and the sensing electrodes RE may be disposed on the second touch insulating layer TINS2. Each of the driving electrodes TE and the sensing electrodes RE may have a single layer or a multilayer made of at least one of molybdenum (Mo), aluminum (Al), chromium (Cr), gold (Au), titanium (Ti), nickel (Ni), neodymium (Nd), copper (Cu), and an alloy thereof.

The driving electrodes TE and the sensing electrodes RE may overlap the connection electrodes BE in the third direction DR3. Each of the driving electrodes TE may be connected to a connection electrode BE through a touch contact hole TCNT1 penetrating the second touch insulating layer TINS2.

The third touch insulating layer TINS3 may be formed on the driving electrodes TE and the sensing electrodes RE. The third touch insulating layer TINS3 may flatten steps formed by the driving electrodes TE, the sensing electrodes RE, and the connection electrodes BE. The third touch insulating layer TINS3 may be made of an organic material such as an acryl resin, an epoxy resin, a phenolic resin, a polyamide resin, or a polyimide resin.

FIG. 7 is a schematic cross-sectional view of a window composite layer 200 according to an embodiment.

Referring to FIG. 7, a cover window 210 may include a groove 211. The groove 211 may be a portion in which a surface (e.g., an upper surface) of the cover window 210 is recessed toward another surface (e.g., a lower surface) in a portion in the folding area FDA. The cover window 210 including the groove 211 may include a step (or inclined surface) between the folding area FDA and the first non-folding area NFA1 and between the folding area FDA and the second non-folding area NFA2.

A surface (e.g., the upper surface) of the cover window 210 may include a bottom surface 210a, inner surfaces 210b, and a top surface 210c. The bottom surface 210a may be a bottom surface of the cover window 210 located inside the groove 211. The inner surfaces 210b may be side surfaces of the cover window 210 located inside the groove 211. The top surface 210c may be a portion of the surface of the cover window 210 where the groove 211 is not disposed.

Although the inner surfaces 210b are straight inclined surfaces in a cross-sectional view in the drawing, the disclosure is not limited thereto. For example, the inner surfaces 210b may be vertical surfaces extending in the third direction DR3. For example, the inner surfaces 210b may be curved inclined surfaces in a cross-sectional view.

The bottom surface 210a may be disposed in the folding area FDA. In an embodiment, a width of the bottom surface 210a may be smaller than the width of the folding area FDA, and the bottom surface 210a may overlap only the folding area FDA, the inner surfaces 210b may overlap the folding area FDA, and the top surface 210c may or may not overlap the folding area FDA in the thickness direction of the display device 10.

In an embodiment, the width of the bottom surface 210a may be equal to the width of the folding area FDA, and each of the inner surfaces 210b and the top surface 210c may be disposed in the first non-folding area NFA1 and the second non-folding area NFA2 and may not overlap the folding area FDA in the thickness direction of the display device 10.

In an embodiment, the width of the bottom surface 210a may be greater than the width of the folding area FDA, and the bottom surface 210a may overlap the folding area FDA, the first non-folding area NFA1, and the second non-folding area NFA2 in the thickness direction of the display device 10. Each of the inner surfaces 210b and the top surface 210c may be disposed in the first non-folding area NFA1 and the second non-folding area NFA2 and may not overlap the folding area FDA in the thickness direction of the display device 10.

In some embodiments, each of the bottom surface 210a and the top surface 210c may be, but is not limited to, a flat surface.

The cover window 210 may include at least two parts having different thicknesses. The cover window 210 may be a hybrid thin window or a slim window having different thicknesses in at least some parts.

For example, the cover window 210 may include a first part 212, a second part 213 disposed on a side and another side of the first part 212, and a third part 214 disposed between the first part 212 and the second part 213. The first part 212 may be a part overlapping the bottom surface 210a in the third direction DR3, the second part 213 may be a part overlapping the top surface 210c in the third direction DR3, and the third part 214 may be a part overlapping the inner surfaces 210b in the third direction DR3.

A thickness H1 of the first part 212 may be smaller than a thickness H2 of the second part 213. The thickness H1 of the first part 212 and the thickness H2 of the second part 213 may be generally constant. For example, the thickness H1 of the first part 212 may be in a range of about 30 μm to about 70 μm, and the thickness H2 of the second part 213 may be in a range of about 60 μm to about 300 μm. For example, the thickness H1 of the first part 212 may be in a range of about 30 μm to about 50 μm, and the thickness H2 of the second part 213 may be in a range of about 60 μm to about 250 μm. A difference between the thickness H2 of the second part 213 and the thickness H1 of the first part 212 may be greater than or equal to about 20 μm. The thickness H1 of the first part 212 and the thickness H2 of the second part 213 are not limited to the above example.

The display device 10 according to the embodiment may have improved impact resistance by including a hybrid thin window or a slim window. Accordingly, since there is no need to additionally place an upper protective layer between the window composite layer 200 and the display panel 400, a thickness of the display device 10 may be reduced. Since the cover window 210 includes the groove 211, the stress applied to the folding area FDA in case that the display device 10 is folded may be minimized.

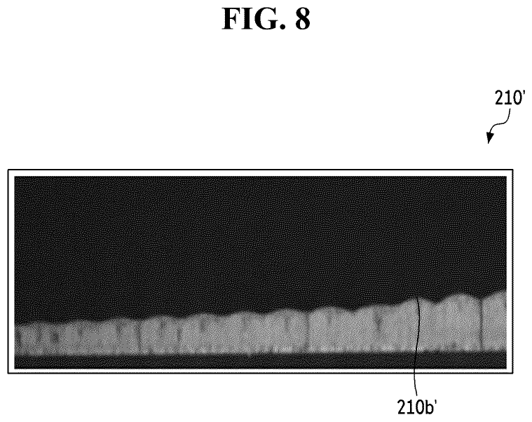

FIG. 8 is a cross-sectional photograph of a portion of a cover window 210′ according to a comparative example.

Referring to FIG. 8 in addition to FIG. 7, an inner surface 210b′ of the cover window 210′ according to the comparative example (a portion corresponding to an inner surface 210b of the cover window 210 according to the embodiment of FIG. 7) may have low flatness. For example, as shown in the photograph of FIG. 8, the inner surface 210b′ of the cover window 210′ according to the comparative example may have irregularities. For example, the inner surface 210b′ of the cover window 210′ according to the comparative example may have relatively low flatness.

As used herein, the term ‘flatness’ refers to a size difference between a largest irregularity and a smallest irregularity. The higher the flatness, the smaller the size difference between the largest irregularity and the smallest irregularity, and the lower the flatness, the greater the size difference between the largest irregularity and the smallest irregularity.

On the other hand, the inner surface 210b of the cover window 210 according to the embodiment may have relatively high flatness. For example, the inner surface 210b of the cover window 210 according to the embodiment may not have irregularities, or even if it includes irregularities, the size difference between the largest irregularity and the smallest irregularity may be relatively small.

In the case of the cover window 210′ according to the comparative example, a photoresist layer may be formed on the cover window 210′. After the photoresist layer is patterned, slimming may be performed using the patterned photoresist layer as a mask.

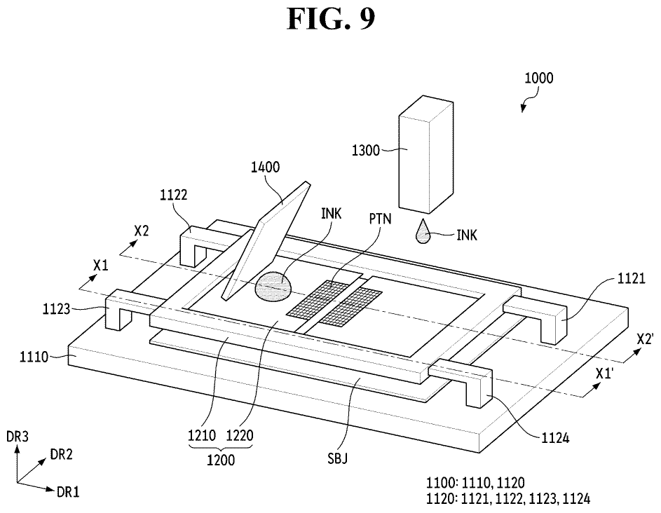

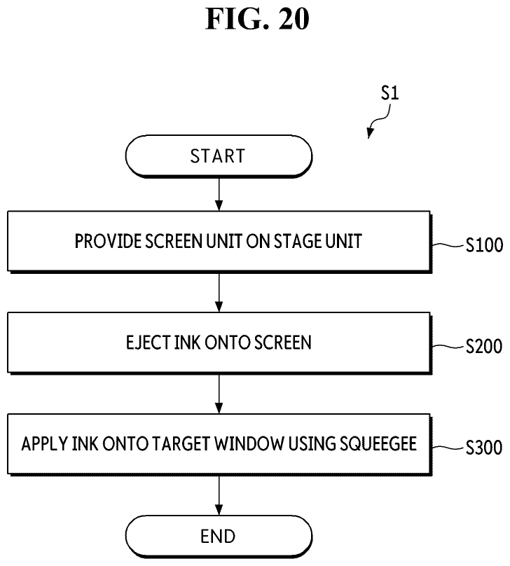

On the other hand, the cover window 210 according to the embodiment may be manufactured using an apparatus 1000 (see FIG. 9) for manufacturing a cover window and a method of manufacturing a cover window (see FIG. 20) which will be described below. Accordingly, the flatness of the cover window 210 may be improved.

An apparatus for manufacturing the cover window 210 according to an embodiment will now be described.

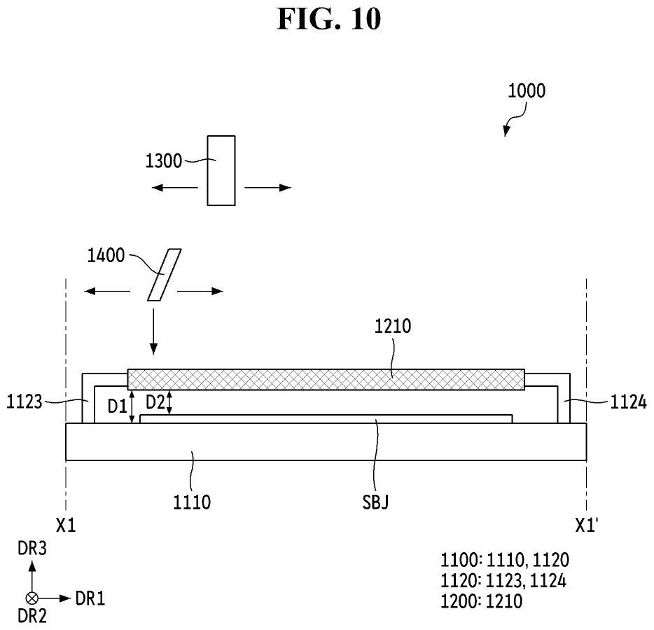

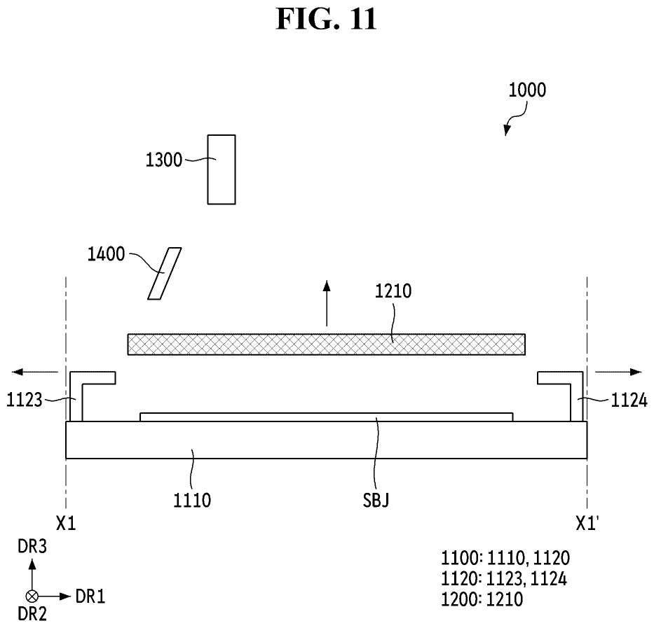

FIG. 9 is a perspective view of an apparatus 1000 for manufacturing a cover window according to an embodiment. FIGS. 10 and 11 are schematic cross-sectional views taken along line X1-X1′ of FIG. 9. FIG. 10 schematically illustrates a state in which a screen unit (or screen part) 1200 is fixed by a frame fixing unit (or frame fixing part) 1120. FIG. 11 schematically illustrates a state in which the screen unit 1200 is detached from the frame fixing unit 1120.

Referring to FIGS. 9 through 11 in addition to FIGS. 7 and 8, the cover window manufacturing apparatus 1000 may be a screen printing device. For example, the cover window manufacturing apparatus 1000 may be a device that slims a target window SBJ by applying ink INK containing an etchant onto the target window SBJ. The cover window manufacturing apparatus 1000 may partially slim the target window SBJ through a screen 1220.

The cover window manufacturing apparatus 1000 may include a stage unit 1100, the screen unit 1200, an ink supply unit (or ink supply part) 1300, and a squeegee 1400.

The stage unit 1100 may include a stage 1110 and a frame fixing unit 1120.

The stage 1110 may provide a space where the target window SBJ may be mounted or placed. The target window SBJ may be placed on the stage 1110 while a process of manufacturing a cover window is being performed.

The frame fixing unit 1120 may be disposed on the stage 1110. The frame fixing unit 1120 may fix the screen unit 1200 described below onto the stage 1110. For example, the frame fixing unit 1120 may fix the screen unit 1200 at a position spaced apart from the stage 1110 by a first distance D1 in the third direction DR3. For example, the frame fixing unit 1120 may fix the screen unit 1200 at a position spaced apart from the target window SBJ by a second distance D2 in the third direction DR3.

In the cover window manufacturing apparatus 1000 according to an embodiment, since the screen unit 1200 is spaced apart from the stage 1110 and the target window SBJ by a distance, the flatness of the cover window 210 may be improved.

For example, as described above, in the case of the cover window 210′ according to the comparative example, since a photoresist layer is formed on the cover window 210′, the cover window 210′ and the photoresist layer may contact (e.g., directly contact) each other, and an initial etched shape formed due to the contact between the photoresist layer and the cover window 210′ may remain on the final cover window 210′ to form irregularities.

On the other hand, in case that the cover window 210 is manufactured using the cover window manufacturing apparatus 1000 according to the embodiment, the initial etched shape may not remain on the final cover window 210 due to the separation of the screen unit 1200 from the target window SBJ. Accordingly, a flat surface may be formed.

In some embodiments, the frame fixing unit 1120 may include a first fixing part 1121, a second fixing part 1122, a third fixing part 1123, and a fourth fixing part 1124. Although the frame fixing unit 1120 includes four fixing parts in the drawings, the disclosure is not limited thereto, and the number of fixing parts may be variously changed.

The first fixing part 1121 and the fourth fixing part 1124 may be located on a side of the screen unit 1200 in the first direction DR1, and the second fixing part 1122 and the third fixing part 1123 may be located on another side of the screen unit 1200 in the first direction DR1.

Each of the first through fourth fixing parts 1121 through 1124 may include a vertical support part extending in the third direction DR3 and a horizontal support part extending in the first direction DR1.

In some embodiments, the first through fourth fixing parts 1121 through 1124 may include a horizontal driver that drives in the first direction DR1. Accordingly, as illustrated in FIGS. 10 and 11, the first through fourth fixing parts 1121 through 1124 may be movable between a side and another side in the first direction DR1 to fix the screen unit 1200 or detach the fixed screen unit 1200, and the horizontal driver may be disposed between the first through fourth fixing parts 1121 through 1124 and the stage 1110.

In an embodiment, the fixing and detaching of the screen unit 1200 may be implemented by changing a length of the horizontal support part of each of the first through fourth fixing parts 1121 through 1124. For example, the horizontal support part of each of the first through fourth fixing parts 1121 through 1124 may include a horizontal driver (not illustrated) that drives in the first direction DR1. The length of the horizontal support part of each of the first through fourth fixing parts 1121 through 1124 in the first direction DR1 may be adjusted by driving the horizontal driver, thereby implementing the fixing and detaching of the screen unit 1200.

In some embodiments, the vertical support part of each of the first through fourth fixing parts 1121 through 1124 may include a vertical driver (not illustrated) that drives in the third direction DR3 to adjust a fixing height of the screen unit 1200.

The screen unit 1200 may include a screen frame 1210 and the screen 1220.

The screen frame 1210 may form the outer shape of the screen unit 1200. The outer shape of the screen frame 1210 may correspond to the shape of the target window SBJ. For example, as illustrated in the drawings, if the shape of the target window SBJ is a quadrangle, the outer shape of the screen frame 1210 may also be a quadrangle in a plan view. However, the disclosure is not limited thereto, and the shape of the target window SBJ may be variously changed, and the outer shape of the screen frame 1210 may be variously changed according to the shape of the target window SBJ.

The screen frame 1210 may have a frame shape with an empty center. For example, an opening may be located in about the center of the screen frame 1210, and the screen 1220 may be disposed in the opening of the screen frame 1210.

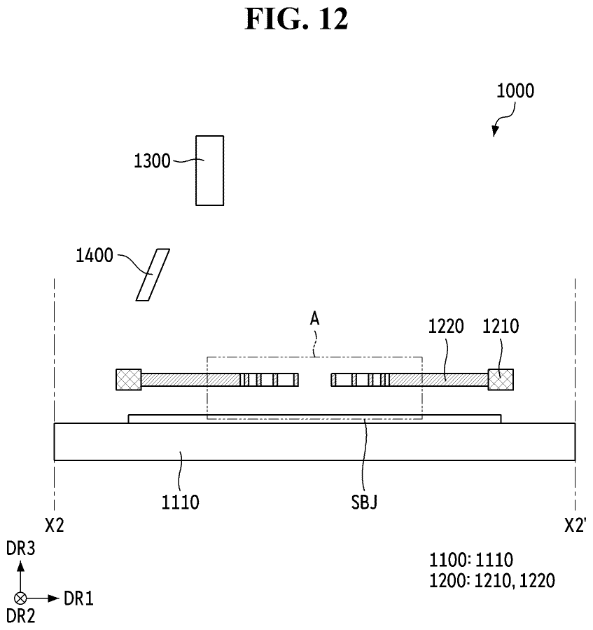

The screen 1220 may be surrounded by the screen frame 1210. The screen 1220 may be disposed in the opening located in the center of the screen frame 1210. The screen 1220 may include a pattern portion PTN. The screen 1220 may control the amount, shape, and position of the ink INK applied onto the target window SBJ through the pattern portion PTN. The screen 1220 will be described below with reference to FIG. 12, etc.

The ink supply unit 1300 may eject the ink INK onto the screen 1220. In an embodiment, the ink supply unit 1300 may eject the ink INK by a dispensing method, but the disclosure is not limited thereto.

The ink INK ejected by the ink supply unit 1300 may contain an etchant that can etch the target window SBJ. For example, the etchant contained in the ink INK may include hydrofluoric acid, but the disclosure is not limited thereto. The ink INK may include at least one of ammonium fluoride (NH₄F), nitric acid (HNO₃), and phosphoric acid (H₃PO₄), in addition to hydrofluoric acid.

The squeegee 1400 may evenly apply the ink INK on the screen 1220. In some embodiments, the squeegee 1400 may include a blade made of rubber, polyurethane, and/or silicone, but the disclosure is not limited thereto.

While moving in the first direction DR1 or the second direction DR2 on the screen 1220, the squeegee 1400 may evenly apply the ink INK on the screen 1220 while moving the ink INK in a moving direction. The squeegee 1400 may apply the ink INK on the target window SBJ through holes of the pattern portion PTN by applying a pressure to the screen 1220.

As illustrated in FIG. 10, each of the ink supply unit 1300 and the squeegee 1400 may include a driver (not illustrated) to move in at least one of the first direction DR1, the second direction DR2, and the third direction DR3.

In some embodiments, the screen unit 1200 may include a material (corrosion-resistant material) that is resistant to the etchant contained in the ink INK. For example, the screen unit 1200 may include a polymer. For example, the screen unit 1200 may include at least one of polytetra fluoroethylene (PTFE), such as Teflon™, polyvinylidene fluoride (PVDF), ethylene tetrafluoroethylene (ETFE), fluorinated ethylene propylene (FEP), and polyvinyl chloride (PVC).

In another embodiment, the screen unit 1200 may include a single metal and/or an alloy. For example, the screen unit 1200 may include at least one of tantalum (Ta), a nickel alloy, and stainless steel. Examples of the nickel alloy may include, but are not limited to, INCONEL™ and HASTELLOY™.

The screen frame 1210 and the screen 1220 of the screen unit 1200 may each include a corrosion-resistant material and may include different materials or a same material.

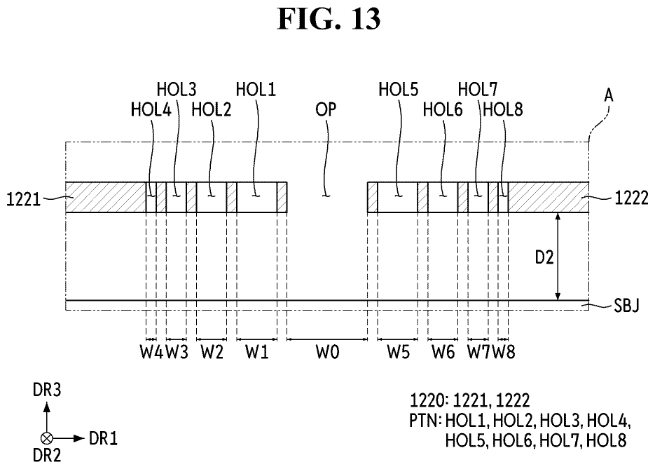

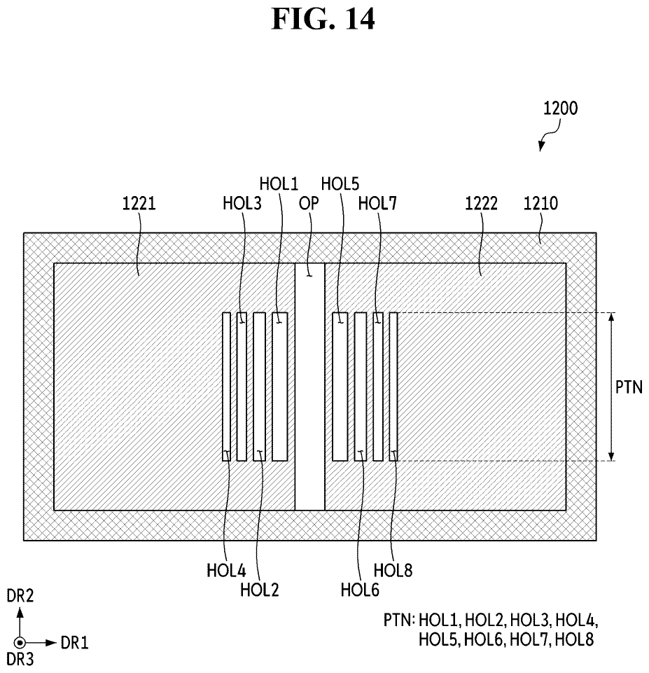

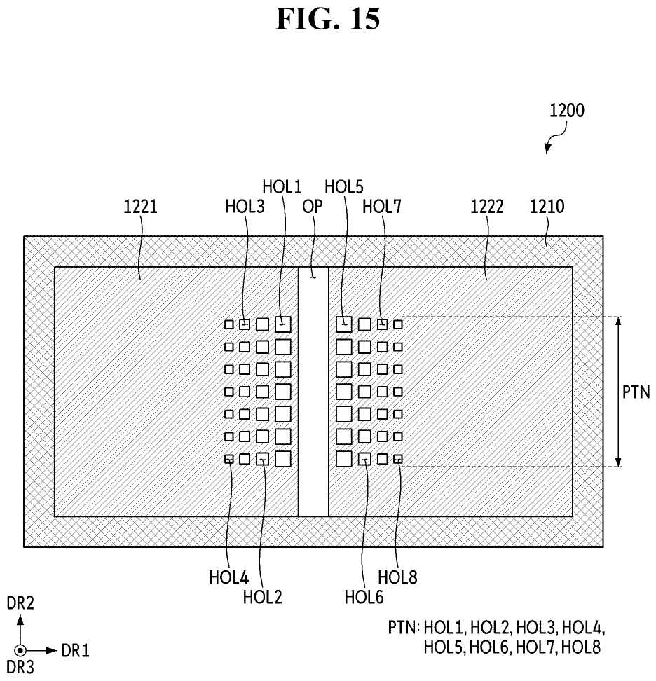

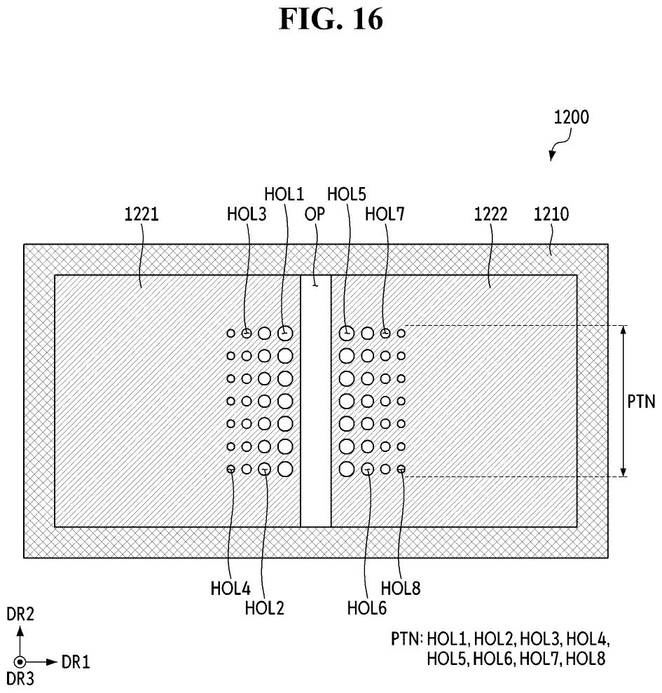

FIG. 12 is a schematic cross-sectional view taken along line X2-X2′ of FIG. 9. FIG. 13 is an enlarged view of area A of FIG. 12. FIG. 14 is a plan view of a screen part 1200 according to an embodiment. FIG. 15 is a plan view of a screen part 1200 according to an embodiment. FIG. 16 is a plan view of a screen part 1200 according to an embodiment.

Referring to FIGS. 12 through 16 in addition to FIG. 9, the screen unit 1200 may include the screen frame 1210 and the screen 1220. Although the screen unit 1200 has a quadrangular shape in a plan view in the drawings, the disclosure is not limited thereto.

As illustrated in FIG. 14, the screen frame 1210 may surround the screen 1220 in a plan view. The screen 1220 may be fixed to an inner surface of the screen frame 1210.

The screen 1220 may include a first screen 1221 and a second screen 1222. The first screen 1221 and the second screen 1222 may be spaced apart from each other in the first direction DR1. For example, a screen opening OP may be located between the first screen 1221 and the second screen 1222.

Each of the first screen 1221 and the second screen 1222 may include at least one hole pattern. For example, the first screen 1221 may include a first hole HOL1, a second hole HOL2, a third hole HOL3, and a fourth hole HOL4, and the second screen 1222 may include a fifth hole HOL5, a sixth hole HOL6, a seventh hole HOL7, and an eighth hole HOL8. The first through eighth holes HOL1 through HOL8 may be spaced apart from each other in the first direction DR1.

Although each of the first screen 1221 and the second screen 1222 includes four holes in the drawings, the disclosure is not limited thereto, and the number of holes may be variously changed. The first through eighth holes HOL1 through HOL8 may be included in the pattern portion PTN.

The first hole HOL1 may be disposed closer to the screen opening OP than the second hole HOL2, the second hole HOL2 may be disposed closer to the screen opening OP than the third hole HOL3, and the third hole HOL3 may be disposed closer to the screen opening OP than the fourth hole HOL4. For example, the first through fourth holes HOL1 through HOL4 may be disposed adjacent to the screen opening OP in the order of the first hole HOL1, the second hole HOL2, the third hole HOL3, and the fourth hole HOLA.

The fifth hole HOL5 may be disposed closer to the screen opening OP than the sixth hole HOL6, the sixth hole HOL6 may be disposed closer to the screen opening OP than the seventh hole HOL7, and the seventh hole HOL7 may be disposed closer to the screen opening OP than the eighth hole HOL8. For example, the fifth through eighth holes HOL5 through HOL8 may be disposed adjacent to the screen opening OP in the order of the fifth hole HOL5, the sixth hole HOL6, the seventh hole HOL7, and the eighth hole HOL8.

Although a width of the pattern portion PTN in the second direction DR2 is smaller than a width of the screen 1220 in the second direction DR2 in the drawings, the disclosure is not limited thereto. For example, the width of the pattern portion PTN in the second direction DR2 may be equal to the width of the screen 1220 in the second direction DR2, and both ends of the first through eighth holes HOL1 through HOL8 of the pattern portion PTN in the second direction DR2 may extend to the inner surface of the screen frame 1210.

In the cover window manufacturing apparatus 1000 according to an embodiment, widths of the first through fourth holes HOL1 through HOL4 may be different from each other, and widths of the fifth through eighth holes HOL5 through HOL8 may be different from each other.

The widths of the first through fourth holes HOL1 through HOLA may decrease from the screen opening OP toward the screen 1220, and the widths of the fifth through eighth holes HOL5 through HOL8 may decrease from the screen opening OP toward the screen 1220.

For example, a width W1 of the first hole HOL1 may be greater than a width W2 of the second hole HOL2, the width W2 of the second hole HOL2 may be greater than a width W3 of the third hole HOL3, and the width W3 of the third hole HOL3 may be greater than a width W4 of the fourth hole HOL4. For example, a width W5 of the fifth hole HOL5 may be greater than a width W6 of the sixth hole HOL6, the width W6 of the sixth hole HOL6 may be greater than a width W7 of the seventh hole HOL7, and the width W7 of the seventh hole HOL7 may be greater than a width W8 of the eighth hole HOL8.

In some embodiments, a width W0 of the screen opening OP may be greater than the width W1 of the first hole HOL1, the width W2 of the second hole HOL2, the width W3 of the third hole HOL3, the width W4 of the fourth hole HOL4, the width W5 of the fifth hole HOL5, the width W6 of the sixth hole HOL6, the width W7 of the seventh hole HOL7, and the width W8 of the eighth hole HOL8.

In the cover window manufacturing apparatus 1000 according to an embodiment, the widths of the openings or holes may decrease in the order of the first hole HOL1, the second hole HOL2, the third hole HOL3 and the fourth hole HOL4 from the screen opening OP, and the widths of the openings or holes may decrease in the order of the fifth hole HOL5, the sixth hole HOL6, the seventh hole HOL7, and the eighth hole HOL8 from the screen opening OP. Therefore, different amounts of ink INK may be applied on the target window SBJ.

Accordingly, of the target window SBJ, a portion located below the screen opening OP may be etched to the greatest degree, a portion located below the first hole HOL1 may be etched to a greater degree than a portion located below the second hole HOL2, the portion located below the second hole HOL2 may be etched to a greater degree than a portion located below the third hole HOL3, and the portion located below the third hole HOL3 may be etched to a greater degree than a portion located below the fourth hole HOL4. Likewise, a portion located below the fifth hole HOL5 may be etched to a greater degree than a portion located below the sixth hole HOL6, the portion located below the sixth hole HOL6 may be etched to a greater degree than a portion located below the seventh hole HOL7, and the portion located below the seventh hole HOL7 may be etched to a greater degree than a portion located below the eighth hole HOL8.

Therefore, a groove 211 (see FIG. 7) may be formed in the target window SBJ as in the cover window 210 (see FIG. 7) described with reference to FIG. 7, and a bottom surface 210a and inner surfaces 210b (see FIG. 7) may be formed.

As described above, since the screen unit 1200 is spaced apart from the target window SBJ by the second distance D2 in the third direction DR3, the flatness of the inner surfaces 210b (see FIG. 7) formed in the target window SBJ may be improved.

In an embodiment, as illustrated in FIG. 14, each of the first through eighth holes HOL1 through HOL8 may have a slit shape in a plan view. For example, each of the first through eighth holes HOL1 through HOL8 may extend in the second direction DR2.

In an embodiment, as illustrated in FIGS. 15 and 16, each of the first through eighth holes HOL1 through HOL8 may have a hole shape in a plan view. For example, as illustrated in FIG. 15, each of the first through eighth holes HOL1 through HOL8 may be a quadrangular hole extending in the first direction DR1 and the second direction DR2. In another embodiment, as illustrated in FIG. 16, each of the first through eighth holes HOL1 through HOL8 may be a circular hole in a plan view.

As illustrated in FIGS. 15 and 16, in case that each of the first through eighth holes HOL1 through HOL8 has a hole shape, sizes or areas of the first through fourth holes HOL1 through HOL4 may be different from each other, and sizes or areas of the fifth through eighth holes HOL5 through HOL8 may be different from each other.

Hereinafter, the cover window manufacturing apparatus according to another embodiment will be described. In the following embodiments, the same elements as those of the above-described embodiment will be indicated by the same reference numerals, and their redundant description will be omitted or given briefly, and differences will be described.

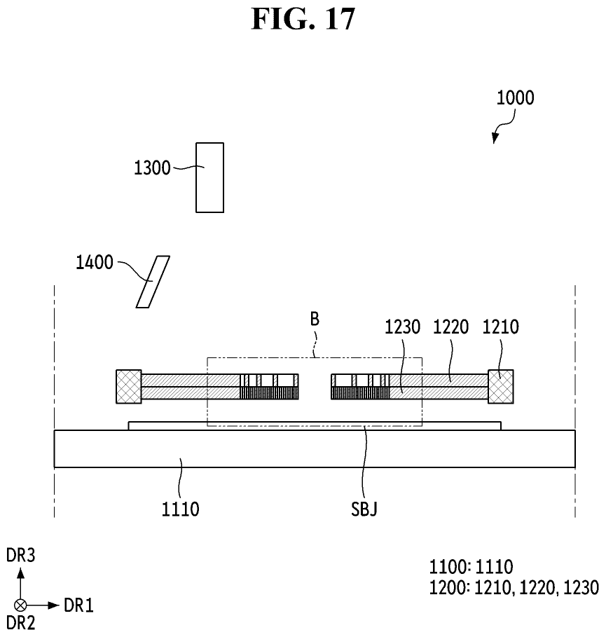

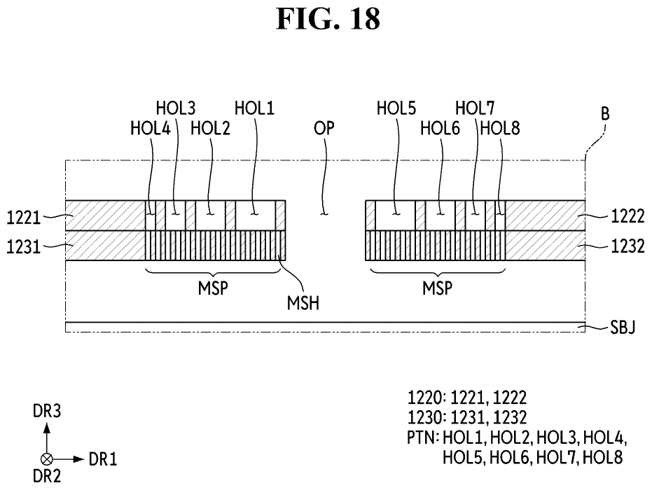

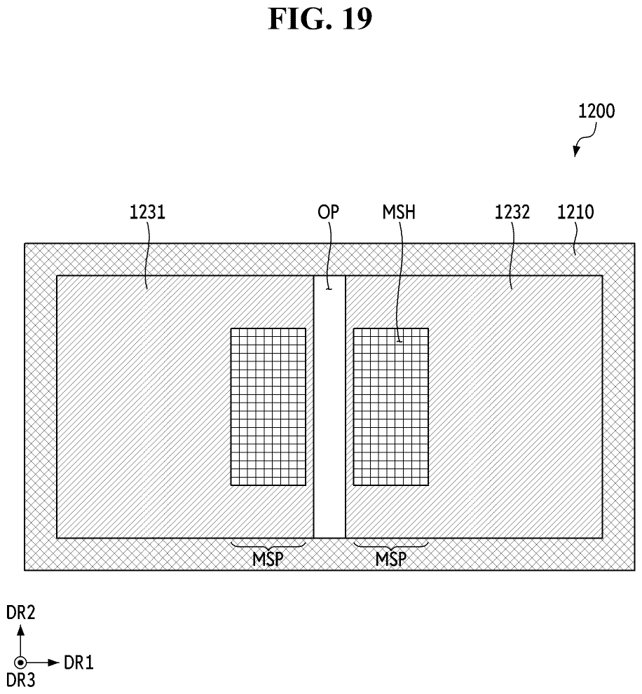

FIG. 17 is a schematic cross-sectional view of an apparatus 1000 for manufacturing a cover window according to an embodiment. FIG. 18 is an enlarged view of area B of FIG. 17. FIG. 19 is a plan view of a screen part 1200 of a cover window according to an embodiment. FIG. 19 illustrates only a screen frame 1210 and an auxiliary screen 1230 of the screen part 1200 and does not illustrate a screen 1220.

Referring to FIGS. 17 through 19, the cover window manufacturing apparatus 1000 according to the embodiment is different from the cover window manufacturing apparatus 1000 according to the embodiment described with reference to FIG. 12, etc. in that the cover window manufacturing apparatus 1000 may further include the auxiliary screen 1230.

In an embodiment, the cover window manufacturing apparatus 1000 may further include the auxiliary screen 1230 disposed below the screen 1220.

The auxiliary screen 1230 may be surrounded by the screen frame 1210 in a plan view. The auxiliary screen 1230 may be disposed in an opening located in a center of the screen frame 1210. The auxiliary screen 1230 may be disposed below the screen 1220. Although the auxiliary screen 1230 has a quadrangular shape in a plan view in the drawings, the disclosure is not limited thereto.

The auxiliary screen 1230 may include a mesh pattern MSP. The mesh pattern MSP may include multiple mesh holes MSH having a constant size and shape. The auxiliary screen 1230 may allow ink INK ejected from a pattern portion PTN of the screen 1220 to be evenly distributed through the mesh pattern MSP.

The auxiliary screen 1230 may include a corrosion-resistant material, like the screen unit 1200 of the cover window manufacturing apparatus 1000 according to the embodiment described with reference to FIG. 12, etc. For example, the auxiliary screen 1230 and the screen unit 1200 of the cover window manufacturing apparatus 1000 described with reference to FIG. 12, etc. may include a same material.

The auxiliary screen 1230 may include a first auxiliary screen 1231 and a second auxiliary screen 1232. The first auxiliary screen 1231 and the second auxiliary screen 1232 may be spaced apart from each other in the first direction DR1. For example, a screen opening OP may be located between the first auxiliary screen 1231 and the second auxiliary screen 1232. The first auxiliary screen 1231 may be located below a first screen 1221, and the second auxiliary screen 1232 may be located below a second screen 1222.

Each of the first auxiliary screen 1231 and the second auxiliary screen 1232 may include the mesh pattern MSP including multiple mesh holes MSH having a constant size and shape. The mesh pattern MSP may extend in the second direction DR2. The mesh pattern MSP of the first auxiliary screen 1231 and the mesh pattern MSP of the second auxiliary screen 1232 may be spaced apart from each other in the first direction DR1 with the screen opening OP interposed between the mesh pattern MSP of the first auxiliary screen 1231 and the mesh pattern MSP of the second auxiliary screen 1232. The mesh pattern MSP of the first auxiliary screen 1231 may be disposed below first through fourth holes HOL1 through HOL4, and the mesh pattern MSP of the second auxiliary screen 1232 may be disposed below fifth through eighth holes HOL5 through HOL8.

In the cover window manufacturing apparatus 1000 according to the embodiment, the ink INK ejected from each of the first through eighth holes HOL1 through HOL8 may be evenly ejected onto a target window SBJ through the mesh pattern MSP of the auxiliary screen 1230.

For example, the ink INK ejected through the first hole HOL1 may be evenly ejected onto a portion of the target window SBJ, which is located below the first hole HOL1, through the mesh holes MSH of the mesh pattern MSP disposed below the first hole HOL1. Likewise, the ink INK ejected through the second hole HOL2 may be evenly ejected to a portion of the target window SBJ, which is located below the second hole HOL2, through the mesh holes MSH of the mesh pattern MSP disposed below the second hole HOL2. Accordingly, the flatness of the cover window 210 may be improved.

A method of manufacturing the cover window 210 using a cover window manufacturing apparatus 1000 will now be described.

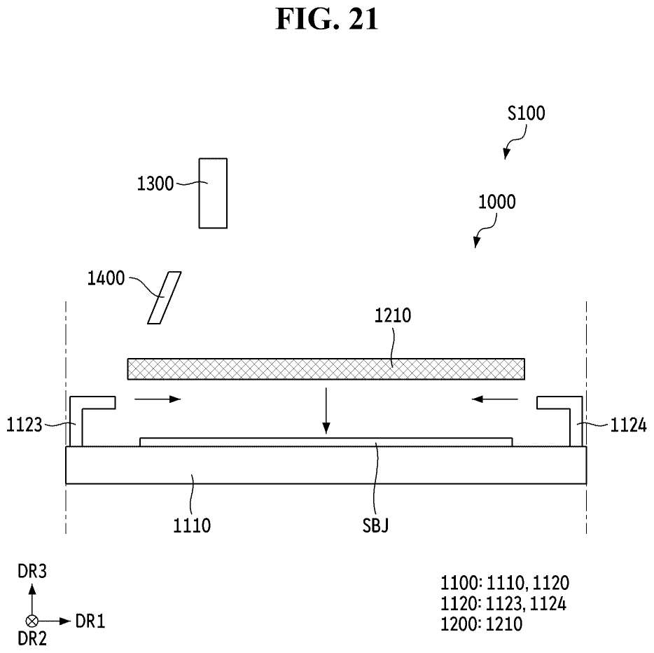

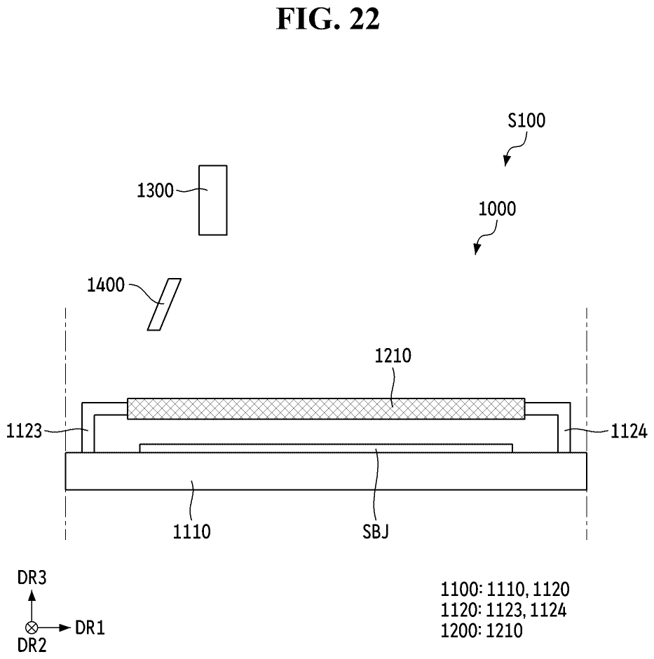

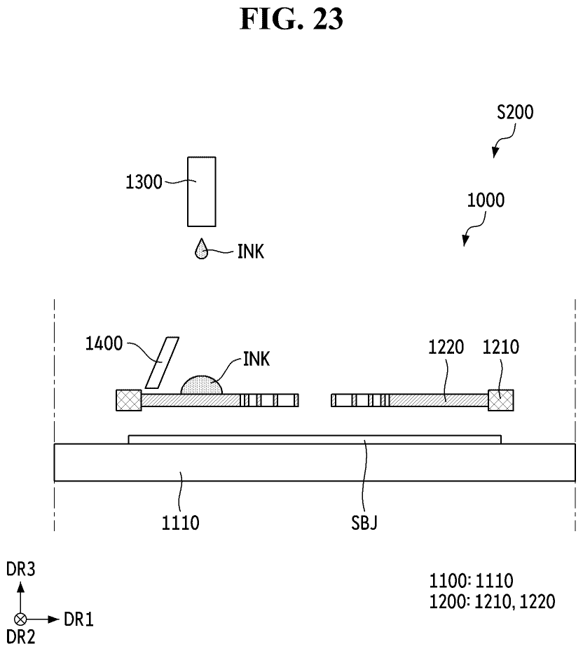

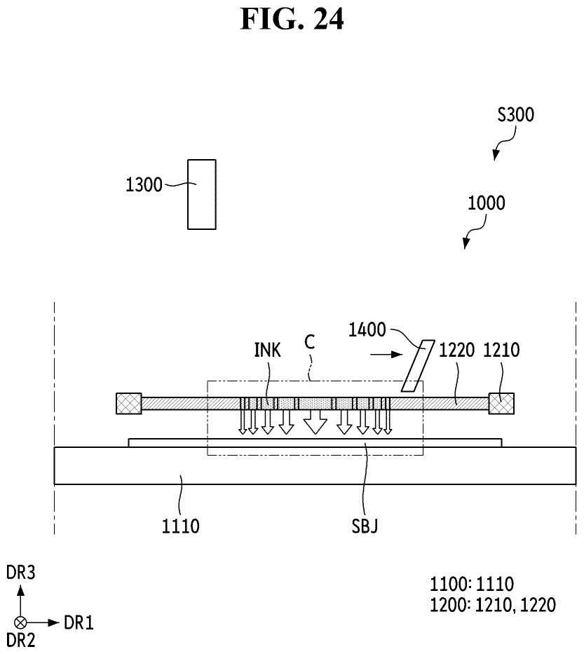

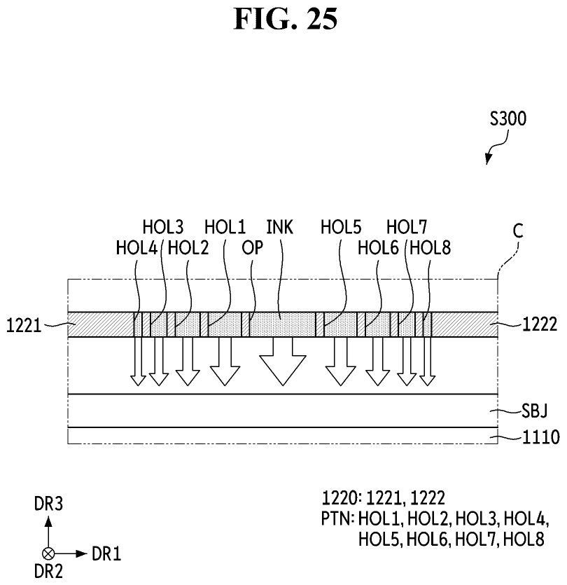

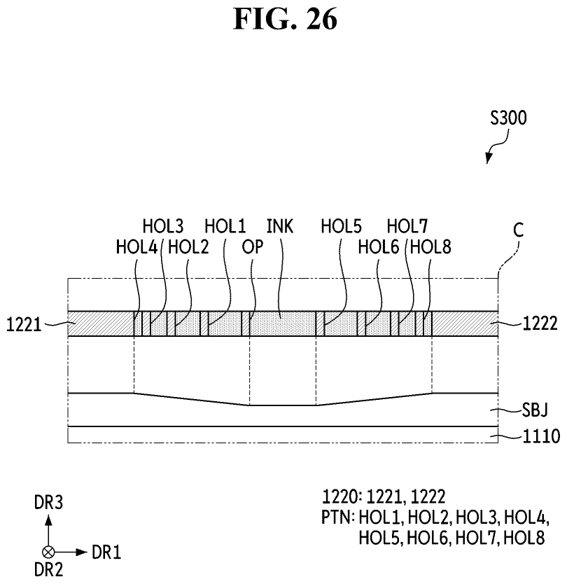

FIG. 20 is a flowchart illustrating a method of manufacturing a cover window according to an embodiment. FIGS. 21 and 22 are schematic cross-sectional views illustrating operation S100 of FIG. 20. FIG. 23 is a schematic cross-sectional view illustrating operation S200 of FIG. 20. FIG. 24 is a schematic cross-sectional view illustrating operation S300 of FIG. 20. FIGS. 25 and 26 are enlarged views of area C of FIG. 24.

Referring to FIGS. 20 through 26, the method S1 of manufacturing the cover window according to an embodiment may include providing a screen unit on a stage unit (operation S100), ejecting ink onto a screen (operation S200), and applying the ink onto a target window using a squeegee (operation S300).

First, as illustrated in FIGS. 21 and 22, in the providing of the screen unit (operation S100), a target window SBJ may be placed on a stage 1110. A screen unit 1200 may be fixed onto the stage 1110 and the target window SBJ by a frame fixing unit 1120.

As illustrated in FIG. 23, in the ejecting of the ink onto the screen (operation S200), an ink supply unit 1300 may eject ink INK onto a screen 1220.

The ink INK may contain an etchant. As described above, the etchant contained in the ink INK may include hydrofluoric acid, but the disclosure is not limited thereto. The ink INK may also include at least one of ammonium fluoride (NH₄F), nitric acid (HNO₃), and phosphoric acid (H₃PO₄), in addition to hydrofluoric acid.

As described above, the screen unit 1200 may include a material (corrosion-resistant material) that is resistant to the etchant contained in the ink INK. Accordingly, the screen unit 1200 may have improved durability and may be used multiple times in a process of manufacturing a cover window 210 (see FIG. 7). Therefore, the process cost may be reduced.

As illustrated in FIGS. 24 through 26, in the applying of the ink onto the target window using the squeegee (operation S300), a squeegee 1400 may push the ink INK in the first direction DR1 by applying a pressure to the screen 1220. By the pressure applied by the squeegee 1400, the ink INK may be ejected onto the target window SBJ through a screen opening OP and first through eighth holes HOL1 through HOL8.

As illustrated in FIG. 25, a largest amount of ink INK may be ejected through the screen opening OP. The amount of ink ejected may decrease in the order of the first through fourth holes HOL1 through HOL4 and may decrease in the order of the fifth through eighth holes HOL5 through HOL8. For example, a difference in arrow thickness in FIG. 25 may indicate a difference in the amount of ink INK ejected.

Accordingly, of the target window SBJ, a portion located below the screen opening OP may be etched to the greatest degree, a portion located below the first hole HOL1 may be etched to a greater degree than a portion located below the second hole HOL2, the portion located below the second hole HOL2 may be etched to a greater degree than a portion located below the third hole HOL3, and the portion located below the third hole HOL3 may be etched to a greater degree than a portion located below the fourth hole HOL4. Likewise, a portion located below the fifth hole HOL5 may be etched to a greater degree than a portion located below the sixth hole HOL6, the portion located below the sixth hole HOL6 may be etched to a greater degree than a portion located below the seventh hole HOL7, and the portion located below the seventh hole HOL7 may be etched to a greater degree than a portion located below the eighth hole HOL8.

Therefore, a bottom surface may be formed in the portion of the target window SBJ which is located below the screen opening OP, and an inclined surface may be formed in the portions located below the first through fourth holes HOL1 through HOL4 and the portions located below the fifth through eighth holes HOL5 through HOL8.

According to the cover window manufacturing method S1 according to the embodiment, since the screen unit 1200 is spaced apart from the target window SBJ in the third direction DR3, the flatness of the inclined surface formed in the target window SBJ may be improved. The process cost may be reduced by reusing the screen unit 1200.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a cover window, the apparatus comprising:
a first screen;
a second screen spaced apart from the first screen; and
a screen opening disposed between the first screen and the second screen, wherein
each of the first screen and the second screen comprises a pattern portion disposed adjacent to the screen opening,
the pattern portion of each of the first screen and the second screen comprises two or more holes spaced apart from each other, and
widths of the two or more holes are different from each other.

2. The apparatus of claim 1, wherein the widths of the two or more holes increase as a distance to the screen opening decreases.

3. The apparatus of claim 1, further comprising:
a screen frame surrounding the first screen and the second screen in a plan view.

4. The apparatus of claim 3, wherein
the first screen and the second screen are spaced apart from each other in a first direction, and
the two or more holes extend in a second direction intersecting the first direction.

5. The apparatus of claim 3, wherein
the first screen and the second screen are spaced apart from each other in a first direction, and
each of the two or more holes is comprised of a plurality of holes spaced apart from each other in a second direction intersecting the first direction.

6. The apparatus of claim 3, wherein ends of the two or more holes are spaced apart from the screen frame.

7. The apparatus of claim 3, further comprising:
a frame fixing part fixing the screen frame, wherein
the screen frame is spaced apart from a target window by the frame fixing part.

8. The apparatus of claim 1, wherein a size of the screen opening is larger than sizes of the two or more holes.

9. The apparatus of claim 1, further comprising:
a squeegee disposed on the first screen and the second screen.

10. The apparatus of claim 1, further comprising:
a stage disposed below the first screen and the second screen.

11. The apparatus of claim 1, further comprising:
an ink supply part ejecting ink containing an etchant and disposed above the first screen and the second screen.

12. The apparatus of claim 1, further comprising:
a first auxiliary screen disposed below the first screen; and
a second auxiliary screen disposed below the second screen,
wherein each of the first auxiliary screen and the second auxiliary screen comprises a mesh pattern overlapping the pattern portion of the first screen or the second screen in a plan view, and
wherein the mesh pattern comprises a plurality of mesh holes having a constant shape and size in a plan view.

13. The apparatus of claim 12, wherein the first auxiliary screen and the second auxiliary screen are spaced apart from each other with the screen opening interposed between the first auxiliary screen and the second auxiliary screen.

14. The apparatus of claim 1, wherein the first screen and the second screen comprise a corrosion-resistant material.

15. An apparatus for manufacturing a cover window, the apparatus comprising:
a stage;
a screen part disposed on the stage and comprising a screen frame, a first screen and a second screen surrounded by the screen frame and spaced apart from each other in a plan view, and a screen opening disposed between the first screen and the second screen; and
a squeegee disposed on the screen part, wherein
each of the first screen and the second screen comprises a pattern portion disposed adjacent to the screen opening,
the pattern portion of each of the first screen and the second screen comprises a first hole and a second hole spaced apart from each other,
the first hole is disposed closer to the screen opening than the second hole, and
a size of the first hole is larger than a size of the second hole.

16. The apparatus of claim 15, further comprising:
a frame fixing part disposed on the stage and fixing the screen part such that the screen part is spaced apart from the stage.

17. The apparatus of claim 15, wherein a size of the screen opening is larger than the sizes of the first hole and the second hole.

18. The apparatus of claim 15, wherein the screen part comprises a corrosion-resistant material.

19. The apparatus of claim 15, further comprising:
an ink supply part ejecting ink containing an etchant and disposed above the screen part.

20. An electronic device comprising:
a processor to provide input image data; and
a display device to display an image based on the input image data, wherein
the display device comprises a display panel and a cover window, and
the cover window is manufactured using the apparatus of claim 1.
